(19) United States
(12) Patent Application Publication
(10) Pub. No.: US 2026/0319371 A1
(43) Pub. Date: Oct. 15, 2026

(54) FILM FORMATION APPARATUS, FILM FORMATION METHOD, AND ARTICLE MANUFACTURING METHOD

(71) Applicant: CANON KABUSHIKI KAISHA, Tokyo (JP)

(72) Inventor: RYOSUKE TSUTSUMI, Tochigi (JP)

(21) Appl. No.: 19/559,012

(22) Filed: Mar. 6, 2026

(30) Foreign Application Priority Data
Apr. 10, 2025 (JP) 2025-065153

(51) Int. Cl. G03F 7/16

(52) U.S. Cl. CPC G03F 7/168

(57) ABSTRACT

A film formation apparatus that performs a film forming process of forming a film of a curable composition on a substrate using a shaping member is provided. The film formation apparatus includes: a substrate holding member that holds the substrate; a first holding member that brings the shaping member into contact with the curable composition on the substrate in a state in which the shaping member is held and releases holding of the shaping member; and a second holding member that holds the shaping member to perform a mold releasing process of separating the shaping member from the cured curable composition after the curable composition has been cured.

### BACKGROUND

### Field of the Technology

The present disclosure relates to a film formation apparatus, a film formation method, and an article manufacturing method.

### DESCRIPTION OF THE RELATED ART

Processes for manufacturing a semiconductor device or the like include a photolithography process of forming a cured film of a composition including minute circuit patterns (unevenness patterns) on a substrate. A technique of flattening a composition on a substrate by shaping the composition on the substrate using a mold including a flat surface is known as a flattening technique.

Japanese Patent Laid-Open No. 2023-47289 discloses a method of deforming a mold to a shape of which a central part is swollen by applying an external pressure to a rear side of a flat surface of the mold and bringing the mold into contact with a composition on a substrate from the central part of the flat surface of the mold. Japanese Patent Laid-Open No. 2020-47649 proposes an apparatus in which a mold holding unit is divided into a plurality of parts and the parts can be independently driven to distribute a bonding force at the time of release of a mold.

In the method disclosed in Japanese Patent Laid-Open No. 2023-47289, an outer peripheral part of the mold is held again by a mold holding unit and the mold and the substrate are separated in order to separate (release) the mold from a cured composition formed between the mold and the substrate. At this time, since the whole rear surface of the substrate is held by suction and only the outer peripheral part of the mold is held by suction, the mold may be dropped (dechucked) from the mold holding unit in the course of separating the mold and the substrate. In the apparatus disclosed in Japanese Patent Laid-Open No. 2020-47649, at the time of separating the mold from the substrate, the whole mold is released from the substrate by starting an operation of separating one part and causing the separation between the mold and the substrate in each part to progress clockwise. In this method, it is considered that local mold release is sequentially performed and thus it takes time to complete release of the whole mold.

### SUMMARY

A film formation apparatus according to an aspect of the present disclosure for achieving the aforementioned objective is a film formation apparatus that performs a film forming process of forming a film of a curable composition on a substrate using a shaping member, the film formation apparatus including: a substrate holding member that holds the substrate; a first holding member that holds the shaping member, brings the shaping member into contact with the curable composition on the substrate, and releases holding of the shaping member; and a second holding member that holds the shaping member to perform a mold releasing process of separating the shaping member from the cured curable composition after the curable composition has been cured.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram schematically illustrating an example of a configuration of a flattening apparatus according to a first embodiment.

FIGS. 2A to 2F are diagrams illustrating a flattening process according to the first embodiment.

FIGS. 3A and 3B are diagrams illustrating a mold releasing process according to the first embodiment.

FIG. 4 is a flowchart illustrating a flattening process using the flattening apparatus according to the first embodiment.

FIGS. 5A to 5F are diagrams illustrating an article manufacturing method.

### DESCRIPTION OF THE EMBODIMENTS

Hereinafter, embodiments will be described in detail with reference to the accompanying drawings. The following embodiments are not intended to limit the disclosures described in the appended claims. A plurality of features are described in the embodiments, all of the plurality of features are not essential to the present disclosure, and the plurality of features may be arbitrarily combined. In the drawings, the same or similar elements will be referred to by the same reference signs, and repeated description thereof will be omitted.

In this specification and the accompanying drawings, directions are described in an XYZ coordinate system in which a direction parallel to a surface of a substrate (or a holding surface holding the substrate, that is, a substrate holding surface 2a which will be described later) is defined as an XY plane unless otherwise mentioned. Directions parallel to an X axis, a Y axis, and a Z axis in the XYZ coordinate system are defined as an X direction, a Y direction, and a Z direction, and rotation around the X axis, rotation around the Y axis, and rotation around the Z axis are defined as θX, θY, and θZ. Control or driving in the X axis, the Y axis, and the Z axis means control or driving in a direction parallel to the X axis, a direction parallel to the Y axis, and a direction parallel to the Z axis. Control or driving in the θX axis, the θY axis, and the θZ axis means control or driving in rotation around an axis parallel to the X axis, rotation around an axis parallel to the Y axis, and rotation around an axis parallel to the Z axis. Positions are information that can be identified on the basis of coordinates in the X axis, the Y axis, and the Z axis, and postures are information that can be identified by values of the θX axis, the θY axis, and the θZ axis.

### First embodiment

In a first embodiment, a flattening apparatus 100 is used as a film formation apparatus. The flattening apparatus is a lithography apparatus that flattens (shapes) a curable composition (a curable material) on a substrate using a mold which is a shaping member and can be employed in a lithography process which is a manufacturing process of a semiconductor device or a magnetic storage medium. A mold used in the flattening apparatus includes a flat surface as a shaping surface (a contact surface) coming into contact with a curable composition (which may be simply referred to as a composition) on a substrate and shaping the composition and may be referred to as a super straight or a flat template. In the following description, a mold including a flat surface may be referred to as a “super straight.”

A base pattern on a substrate may have a height difference of unevenness due to patterns formed in a previous process, and the height difference may depart from a depth of focus (DOF) of an exposure apparatus used in a subsequent process when the height difference is large. In the related art, techniques of forming a flattened layer such as spin on carbon (SOC) or chemical mechanical polishing (CMP) have been used as a method of smoothing the base pattern on the substrate. However, the height difference of the base unevenness due to an increase in the number of layers tends to increase every year. In recent photolithography processes, a depth of focus (DOF) at which a projected image of a minute circuit pattern is formed becomes smaller with an increase in NA. For example, these days, the DOF allowed for an EUV lithography apparatus with NA=0.55 ranges from 160 nm to 40 nm (which depends on an illumination mode). However, with a method of applying an SOC film using a spin coater in the related art, it is known that it is difficult to obtain surface flattening performance enough to meet such an allowable range. Accordingly, there is need for a flattening technique for forming a flat film (that is, a film having a flat surface) on the substrate.

In order to solve this problem, the flattening apparatus according to the present embodiment performs flattening of a curable composition on a substrate using a mold with a flat surface. Specifically, a curable composition is cured in a state in which the flat surface of the mold is brought into contact with the curable composition supplied onto a substrate, and the mold is separated (released) from the cured composition. Accordingly, a flattened film (a flattened layer) formed of a cured composition can be formed on the substrate. The mold used in this flattening technique may be referred to as a super straight or a planar template.

A composition (also referred to as an uncured resin) that is cured by applying curing energy thereto is used as the curable composition. Electromagnetic waves, heat, or the like can be used as the curing energy. For example, light such as infrared light, visible light, or ultraviolet light which is selected from a range of wavelengths of 10 nm to 1 mm can be used as the electromagnetic waves. The curable composition may be a composition which is cured by irradiation with light or by heating. A photo-curable composition which is cured by irradiation with light contains at least a polymerizable compound and a photopolymerization initiator and may further contain a non-polymerizable compound or a solvent according to necessity. The non-polymerizable compound is at least one selected from a group consisting of a sensitizer, a hydrogen donor, an internally added mold releasing agent, a surfactant, an antioxidant, and polymer components. The composition may be disposed in a droplet form or an island form or a film form in which a plurality of droplets are connected on a substrate by a composition supply unit (a supply unit 20 which will be described later). For example, the composition dropped onto the substrate can be disposed as semispherical droplets with a small volume of a diameter of about 10 μm to 20 μm on the substrate. The viscosity (viscosity at 25° C) of the composition may be, for example, equal to or greater than 1 mPa⋅s and equal to or less than 100 mPa⋅s.

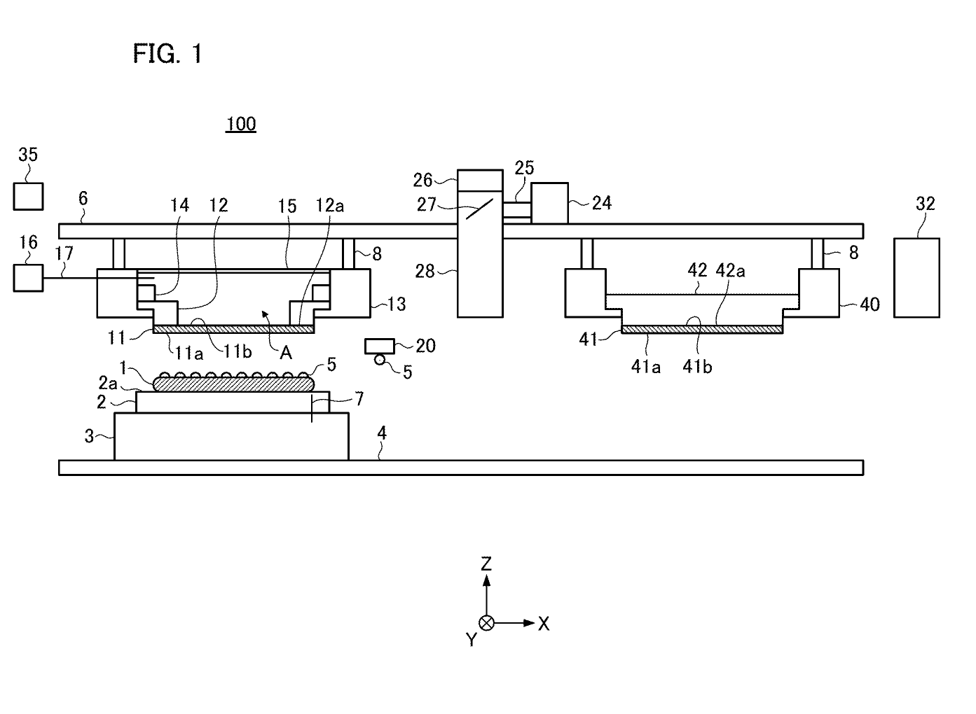

FIG. 1 is a diagram schematically illustrating an example of a configuration of a flattening apparatus 100 according to the present embodiment. In FIG. 1, a substrate 1 is carried into the flattening apparatus 100 by a substrate carrying unit (not illustrated) including a carrying hand and is held by a substrate holding surface 2a of a substrate chuck 2 which is a substrate holding member. A substrate stage 3 is configured to be movable on a base plate 4 and drives the substrate 1 in the X direction and the Y direction by driving the substrate chuck 2 in order to align the substrate 1 held by the substrate chuck 2 at a predetermined position.

For example, glass, ceramic, metal, semiconductor, or resin can be used as the material of the substrate 1. According to necessity, a member formed of a material different from that of the substrate 1 may be provided on the surface of the substrate 1. The substrate 1 is, for example, a silicon wafer, a compound semiconductor wafer, or a quartz glass wafer. The substrate 1 has an uneven structure due to patterns formed in a previous process, and the flattening apparatus 100 can be used to form a flattened film covering the uneven structure on a substrate. A cutout called a notch is formed at an outer peripheral end of the substrate 1, and a θ (rotation) position when seen from the +Z side of the substrate 1 can be aligned with the substrate chuck 2 on the basis of the position in the XY direction of the notch.

A super straight 11 (a first shaping member) can be formed of a material (such as quartz glass) transmitting light. The shape of the super straight 11 is circular, for example, when seen from the +Z side. A shaping surface for coming into contact with a composition 5 on the substrate 1 to shape the composition 5 is a flat surface 11a. When the flat surface 11a of the super straight 11 comes into contact with the composition 5 on the substrate 1, the super straight 11 can be deformed to emulate the surface shape (an uneven shape when seen in the X direction or the Y direction) of the substrate 1 due to the surface tension of the composition 5. For example, the outer diameter of the super straight 11 is the same as the outer diameter of the substrate 1.

A super straight 41 (a second shaping member) is a super straight different from the super straight 11, but the super straight 41 being of the same material and shape as the super straight 11 and including a flat surface 41a. In the flattening apparatus 100 according to the present embodiment, a flattening process is performed on a plurality of substrates 1 using the super straight 11 and the super straight 41. Here, the number of super straights is not limited to two, and three or more super straights may be used.

The super straight 11 is carried into the flattening apparatus 100 by a mold carrying unit (not illustrated) and is held by a holding member 12 (a first mold holding member, a first mold chuck) which is a first holding member. On the other hand, the super straight 41 is handed over from a holding member 42 (a second mold holding member, a second mold chuck) which is a second holding member to a mold carrying unit (not illustrated) and is carried out of the flattening apparatus 100. Since the super straight has the same shape as the substrate 1, the mold carrying unit may be the same as the substrate carrying unit. The mold carrying unit carrying the super straight into the flattening apparatus 100 and the mold carrying unit carrying the super straight out of the flattening apparatus 100 may be different units or may be the same unit.

The holding member 12 holds the super straight 11 by coming into contact with an outer peripheral part of a rear surface 11b (the opposite surface to the flat surface 11a) of the super straight 11 and attracting the outer peripheral part. Holding of the super straight 11 with the holding member 12 can be performed, for example, by vacuum suction of the outer peripheral part of the super straight 11. The method of holding the super straight 11 with the holding member 12 is not limited to vacuum suction, and, for example, electrostatic attraction may be used.

On the other hand, the holding member 42 holds the super straight 41 by coming into contact with a rear surface 41b (the opposite surface to the flat surface 41a) of the super straight 41 using a mold holding surface 42a and attracting the whole rear surface. Holding of the super straight 41 with the holding member 42 can be performed, for example, by vacuum suction of the whole rear surface of the super straight 41 using the mold holding surface 42a. The method of holding the super straight 41 with the holding member 42 is not limited to vacuum suction, and, for example, electrostatic attraction may be used. Here, the mold holding surface 42a is not limited to a configuration in which the mold holding surface 42a is in contact with the whole rear surface 41b of the super straight 41 and has only to be held with a larger contact area than a contact area of the holding member 12. For example, the holding member 42 comes into contact with and holds the outer peripheral part of the super straight 41 similarly to the holding member 12, and the holding member 42 may hold a greater part inside the outer peripheral part in order to hold the rear surface with a larger contact area than that of the holding member 12.

The holding member 12 is supported by a head 13 (a first head). The head 13 includes a drive mechanism for driving the super straight 11 by driving the holding member 12. For example, the head 13 drives the holding member 12 in the Z-axis direction to bring the super straight 11 into contact with the composition 5 on the substrate 1. The head 13 may have a function of correcting a tilt of the holding member 12.

The holding member 42 is supported by a head 40 (a second head). The head 40 has the same configuration as the head 13 and drives the holding member 42 in the Z-axis direction to separate the super straight 41 from the cured composition 5 on the substrate 1.

The drive mechanisms of the head 13 and the head 40 are constituted, for example, by an actuator such as a linear motor, an air cylinder, or a voice coil motor. The head 13 and the head 40 are fixed to a guide bar 8 suspended from a bridge structure 6. The bridge structure 6 is supported by posts (not illustrated) fixed to the base plate 4.

Here, the holding member 12 is supported by the head 13 such that the holding member 12 can be tilted with respect to the head 13 according to the shape of the rear surface 11b in a state in which the holding surface 12a (the surface holding the super straight 11) is in contact with the rear surface 11b of the super straight 11. That is, the holding member 12 has flexibility enough to be tilted according to the shape of the super straight 11. For example, when an external force is applied to the super straight 11 held by the holding member 12 and the whole super straight 11 is wholly bent and deformed in a shape which is convex downward (to the –Z direction), the holding member 12 is tilted such that the holding surface 12a faces the outside. Accordingly, the shape of the super straight 11 can be kept in a quadratic curved surface which is a shape which is convex downward.

A force detecting unit 14 that detects a pressing force on the super straight 11 by the holding member 12 is provided in the head 13. The force detecting unit 14 detects an external force transmitted to the holding member 12 via the super straight 11 and can be used to detect a pressing force when the super straight 11 is brought into contact with the substrate 1. For example, a strain gauge type load sensor or a load sensor (a load cell) that detects a force from a current value applied to the drive mechanism (actuator) of the head 13 can be used as the force detecting unit 14.

A plate optical device 15 (a light transmitting member) formed of a light-transmitting member such as quartz glass is provided in the head 13. The plate optical device 15 is attached to the head 13 such that a space region A which is a closed space is formed between the super straight 11 and the plate optical device 15. That is, the plate optical device 15 serves as a seal member for making a space region A above the super straight 11 surrounded by the holding member 12 and the super straight 11 held by the holding member 12 a closed space. An internal pressure of the space region A can be adjusted (controlled) by a pressure adjusting unit 16 via a pipe 17. For example, the pressure adjusting unit 16 can deform the super straight 11 to a shape which is convex downward by setting the internal pressure of the space region A to be higher than the atmospheric pressure and bring the super straight 11 into contact with the composition 5 on the substrate 1 gradually from a central part thereof. In the flattening technique, a super straight of which the area of the flat surface is equal to or slightly larger than the area of the substrate is used as a mold (for example, about 2% to 4%). In order to form a liquid film of the composition with a uniform thickness between the super straight and the substrate such that the flat surface of the super straight emulates unevenness of the substrate surface, the thickness of the super straight ranges from about 500 μm to 800 μm. The super straight can be easily deformed with an external pressure. When the whole flat surface of the super straight is almost simultaneously brought into contact with the composition on the substrate at the time of bringing the flat surface of the super straight into contact with the composition on the substrate, gas may be enclosed between the super straight and the substrate, and thus the thickness of the liquid film may be non-uniform. Accordingly, at the time of bringing the super straight 11 into contact with the composition 5 on the substrate 1, the super straight 11 is deformed to a shape which is convex downward, and the super straight 11 is gradually brought into contact with the composition 5 on the substrate 1 from the central part thereof. Accordingly, it is possible to reduce enclosure of bubbles between the super straight 11 and the substrate 1.

A curing unit 24 cures the composition 5 by emitting light (for example, ultraviolet) which is curing energy to the liquid film of the composition 5 formed between the super straight 11 and the substrate 1 in the flattening process. The curing unit 24 in the present embodiment includes a light source constituted by a UV lamp or a UV LED. Light emitted from the curing unit 24 passes through an optical path tube 25 including a collimator lens (not illustrated), is reflected from a mirror 27, is emitted from an opening unit 28 (an emission unit), and is applied to the composition 5 on the substrate 1 via the super straight 11. The opening unit 28 is disposed at a position different in the XY plane direction (the X direction herein) from the holding member 12, the head 13 supporting the holding member 12, the holding member 42, and the head 40 supporting the holding member 42. In order to cure the composition 5 between the super straight 11 and the substrate 1, the substrate stage 3 is moved in the XY direction, and the substrate stage 3 is located below the opening unit 28. In order to move the substrate stage 3 below the opening unit 28 in a state in which the super straight 11 is put on the substrate 1, holding of the super straight 11 with the holding member 12 is released in advance.

A spread camera 26 is a camera for detecting (observing) a contact state between the super straight 11 and the composition 5 on the substrate 1, that is, a liquid film state of the composition 5 formed between the super straight 11 and the substrate 1. The spread camera 26 includes, for example, a wide-angle camera and has a wide field of view (angle of view) which is not limited to the size of the opening unit 28 and which can detect (observe) the whole area of the substrate 1. Here, when the contact state between the super straight 11 and the composition 5 on the substrate 1 is detected by the spread camera 26, the mirror 27 can retract from the field of view of the spread camera 26. The present disclosure is not limited thereto, and the mirror 27 may be constituted by a half mirror which reflects light from the curing unit 24 and transmitting light to the spread camera 26. Although not illustrated, a spread camera may be additionally provided just above the head 13 (the first head). In this case, a contact status between the super straight and the substrate (a status in which the super straight is gradually brought into contact with the substrate from the center to the outer edge) with lowering of the super straight by the head 13 can be observed.

A supply unit 20 supplies a composition 5 onto the substrate 1. The supply unit 20 in the present embodiment is constituted by a dispenser including an ejection port (nozzle) for ejecting a composition 5 (a resin in an uncured state) onto the substrate 1. For example, the supply unit 20 employs a piezoelectric jet system or a micro solenoid system and is configured to jet a composition 5 as a plurality of droplets with a small volume of 1 pL (picoliter). By causing the supply unit 20 to eject the composition 5 as a plurality of droplets in a state in which the substrate 1 is being moved in the XY direction below the supply unit 20 by the substrate stage 3, it is possible to supply the composition 5 as a plurality of droplets to the whole area of the substrate 1.

A push pin 7 provided in the substrate stage 3 has an assistance function when the super straight 11 is released from the cured composition 5 on the substrate 1. Specifically, when the super straight 11 is released, the push pin 7 is made to protrude to the super straight 11 via a gap area of a cutout such as a notch or an orientation flat of the substrate 1. By causing the push pin 7 to protrude and to push the super straight 11 in a state in which the substrate 1 is held by the substrate chuck 2, a force can be applied in a direction in which the super straight 11 is separated from the substrate 1 and assist with the mold releasing process of the super straight 11.

An inspection unit 32 inspects the super straight 41 recovered from the holding member 42. Specifically, the inspection unit 32 performs inspection of flatness of the flat surface 41a of the super straight 41, inspection of whether there are particles (particulates) or scratches (stains) on the flat surface 41a and the rear surface 41b, inspection of attachment of foreign matter, or the like. The inspection unit 32 includes, for example, a laser measuring device or an optical profiler and inspects the super straight 41 in a noncontact manner using them.

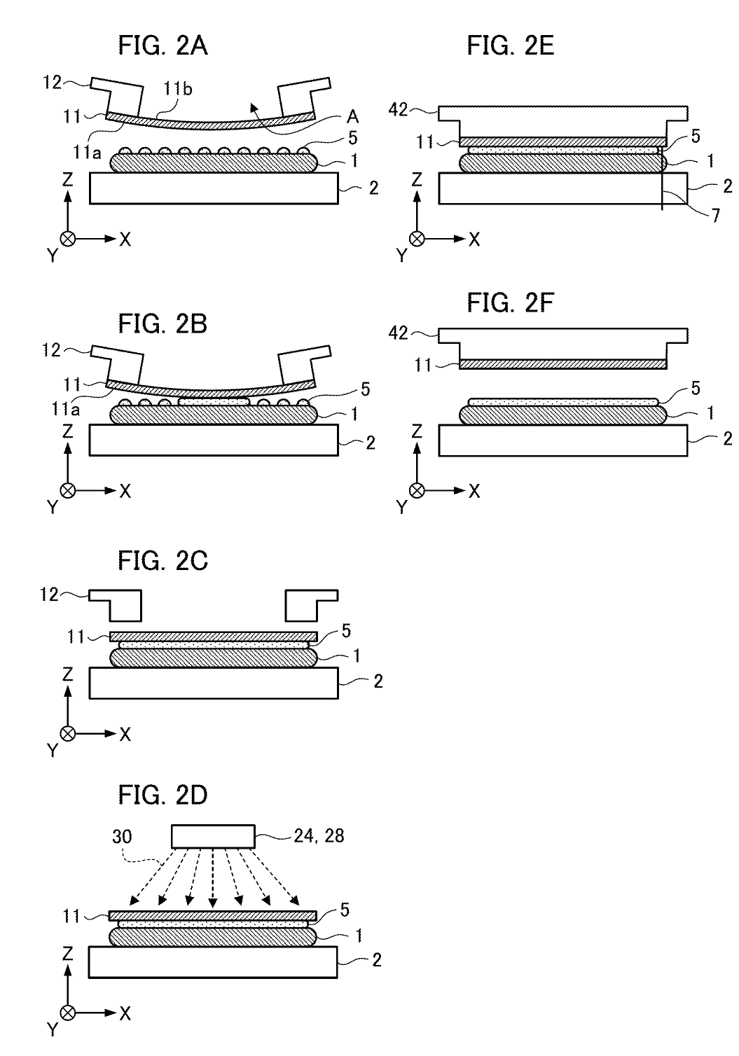

A controller 35 is constituted by a computer (an information processing device) including a processor such as a central processing unit (CPU) and a storage unit such as a memory. The controller 35 is connected to the constituents of the flattening apparatus 100 via lines and controls a flattening process which is a film forming process by comprehensively controlling the constituents of the flattening apparatus 100. The flattening process is a process of flattening the composition 5 on the substrate 1 by bringing the flat surface 11a of the super straight 11 into contact with the composition 5 on the substrate 1 and causing the flat surface 11a to emulate the surface shape of the substrate 1. In the present embodiment, the controller 35 can determine a contact state between the super straight 11 and the composition 5 on the substrate 1 on the basis of image information acquired from the spread camera 26. The controller 35 may be constituted by a programmable logic device (PLD) such as a field-programmable gate array (FPGA) or an application-specific integrated circuit (ASIC).

[The flattening process will be described below with reference to FIGS. 2A to 2F. FIGS. 2A to 2F are diagrams illustrating the flattening process according to the first embodiment. In FIG. 2, only elements required for description of the flattening process are illustrated, and other elements are not illustrated.

FIG. 2A illustrates a state before the super straight 11 and the composition 5 on the substrate 1 are brought into contact with each other. In FIG. 2A, a composition 5 supplied as a plurality of droplets by the supply unit 20 is disposed on a substrate 1. The droplets of the composition 5 are disposed on the substrate 1 in a separated state. A supply pattern (a disposal pattern) of the droplets of the composition 5 on the substrate 1 can be determined in advance on the basis of step differences of a base pattern formed on the surface of the substrate 1. However, unevenness of the substrate 1 itself in addition to the step differences of the base pattern are present on the actual substrate 1. Accordingly, the supply pattern may be determined on the basis of the step differences of the base pattern and the unevenness of the substrate 1 itself.

When the super straight 11 and the composition 5 on the substrate 1 are brought into contact with each other, the super straight 11 can be deformed to a convex shape in which the central part thereof protrudes to the substrate 1 in order to reduce enclosure of bubbles between the super straight 11 and the substrate 1. Specifically, by causing the pressure adjusting unit 16 to increase the internal pressure of the space region A which is a closed space, the super straight 11 can be deformed in a convex shape as illustrated in FIG. 2A. At this time, the holding member 12 is tilted such that the holding surface thereof faces the outside. Accordingly, the flat surface 11a of the super straight 11 becomes a quadratic curved surface such that the central part of the flat surface 11a is closest to the substrate 1.

FIG. 2B illustrates a state just after the super straight 11 has been brought into contact with the composition 5 on the substrate 1. For example, in a state in which the flat surface 11a of the super straight 11 has been deformed to a convex shape by causing the pressure adjusting unit 16 to increase the internal pressure of the space region A, the super straight 11 (the holding member 12) is lowered by the head 13. Accordingly, contact between the flat surface 11a of the super straight 11 and the composition 5 on the substrate 1 can be started from the central part of the super straight 11. Thereafter, by causing the pressure adjusting unit 16 to decrease the internal pressure of the space region A in parallel with further lowering of the super straight 11, the flat surface 11a of the super straight 11 is returned to the flat shape. Accordingly, the composition 5 on the substrate 1 is spread to the outside of the substrate 1 along the flat surface 11a of the super straight 11. Starting of the contact between the super straight 11 and the substrate 1 is determined by the force detecting unit 14. When the force detecting unit 14 detects starting of the contact between the super straight 11 and the substrate 1, the lowering operation of the super straight 11 and the internal pressure of the space region A using the pressure adjusting unit 16 are controlled, for example, such that the pressing force applied to the force detecting unit 14 is constant.

Here, in a state in which the super straight 11 is held by the holding member 12, the super straight 11 does not emulate the surface shape of the substrate 1 due to that holding and it is difficult to form a continuous liquid film of the composition 5 between the super straight 11 and the substrate 1. Accordingly, in the flattening process, the holding of the super straight 11 with the holding member 12 is released as will be described later with reference to FIG. 2C. “It is difficult to form a continuous liquid film of the composition 5” means, for example, that a part in which the composition 5 remains as droplets and/or a part with uneven thicknesses can be present between the super straight 11 and the substrate 1.

FIG. 2C illustrates a state in which the holding of the super straight 11 with the holding member 12 has been released. By releasing the holding of the super straight 11 with the holding member 12, a pressing force based on the mass of the super straight 11 is uniformly applied to the composition 5 (which includes the outer peripheral part) on the substrate 1. Accordingly, the super straight 11 can be made to emulate the surface shape of the substrate 1, and a liquid film of the composition 5 is formed between the super straight 11 and the substrate 1. Here, in FIG. 2C, a state in which the holding member 12 and the super straight 11 have been released (separated) is illustrated for distinction from the state of FIG. 2B. When the holding member 12 is configured to hold the super straight 11 by vacuum suction, release of the holding of the super straight 11 with the holding member 12 may be understood as stopping of the vacuum suction of the super straight 11 with the holding member 12.

In this way, in the flattening process, the holding of the super straight 11 with the holding member 12 is released after the holding member 12 has been driven by the head 13 to bring the super straight 11 into contact with the composition 5 on the substrate 1. By employing this process, it is possible to form a liquid film of the composition 5 between the super straight 11 and the substrate 1.

FIG. 2D illustrates a state in which the liquid film of the composition 5 formed between the super straight 11 and the substrate 1 is cured. Specifically, after the holding of the super straight 11 with the holding member 12 has been released as illustrated in FIG. 2C, the substrate stage 3 is moved in the XY direction such that the substrate stage 3 is located below the opening unit 28. Then, a liquid film formation state of the composition 5 interposed between the super straight 11 and the substrate 1 is observed using the spread camera 26. When the liquid film is satisfactorily formed over the outer peripheral part of the substrate 1, light 30 is emitted from the curing unit 24 in this state, and the light 30 is applied to the liquid film of the composition 5 via the super straight 11. Accordingly, the composition 5 (the liquid film) between the super straight 11 and the substrate 1 is cured. Here, when the light 30 from the curing unit 24 does not spread sufficiently widely over the whole liquid film of the composition 5, that is, when the light 30 is not applied to an end portion of the substrate 1, the substrate stage 3 may be moved in the XY direction such that the end portion of the substrate 1 is irradiated with the light 30.

FIG. 2E illustrates a state in which the mold releasing process for separating the super straight 11 from the cured composition 5 on the substrate 1 is started. After the process of curing the composition 5 on the substrate 1 has been completed through the curing process illustrated in FIG. 2D, the substrate stage 3 is moved in the XY direction such that the substrate stage 3 is located below the holding member 42. Then, by lowering the holding member 42 using the head 40, the holding member 42 is brought into contact with the super straight 11, and the super straight 11 is held by the holding member 42. Here, when the holding member 42 is configured to hold the super straight 11 by vacuum suction, the holding of the super straight 11 with the holding member 42 may be understood as starting of the vacuum suction of the super straight 11 with the holding member 42. In order to assist with the mold releasing process, the push pin 7 is driven upward to press the tip of the push pin on the super straight 11. Accordingly, separation of the super straight 11 and the composition 5 is started with the position pressed with the push pin 7 as a start point.

FIG. 2F illustrates a state in which the mold releasing process for separating the super straight 11 from the cured composition 5 on the substrate 1 has been ended. By raising the holding member 42 using the head 40 after the super straight 11 has been held by the holding member 42, the super straight 11 held by the holding member 42 is separated from the cured composition 5. Accordingly, it is possible to form a flattened film (a flattened layer) formed of the cured composition 5 in the whole area of the substrate 1.

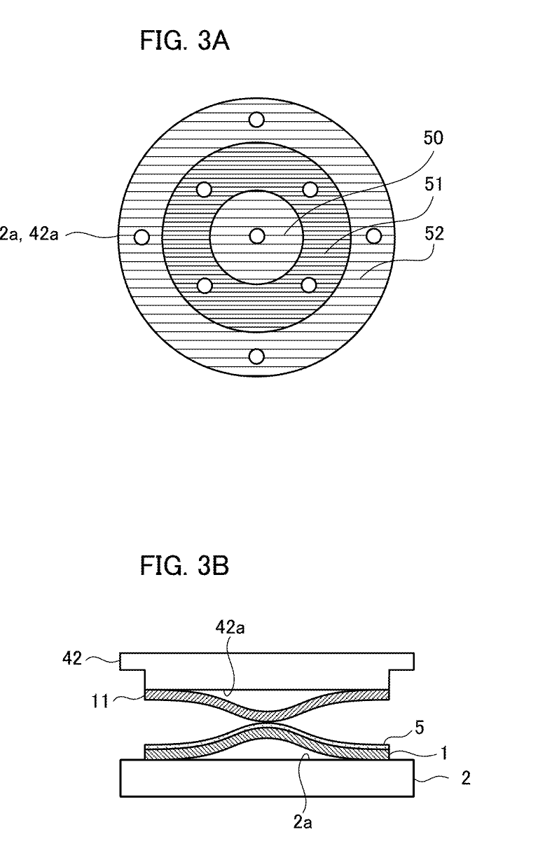

FIGS. 3A and 3B are diagrams specifically illustrating the mold releasing process according to the first embodiment. FIG. 3A is a diagram illustrating an example of the configurations of the substrate holding surface 2a of the substrate chuck 2 and the mold holding surface 42a of the holding member 42. As illustrated in FIG. 3A, each of the substrate holding surface 2a of the substrate chuck 2 which is a substrate holding member and the mold holding surface 42a of the holding member 42 holding the super straight is divided into two or more regions, and a holding state of each region can be independently controlled. That is, the substrate chuck 2 and the holding member 42 can hold the substrate 1 or the super straight with at least different holding forces in the outer peripheral part and the inner part. For example, when holding of the substrate or the super straight is performed by vacuum suction, a suction force (a holding force) can be changed depending on the regions (for example, -100 kPa to +50 kPa). In the example illustrated in FIG. 3A, the holding surface is radially divided into three regions including a central region 50, an intermediate region 51, and an outer peripheral region 52. Small circles illustrated in the three regions exemplify holes through which suction is performed. The central region 50, the intermediate region 51, and the outer peripheral region 52 can hold the substrate or the super straight with different suction forces (holding forces). In FIG. 3A, the substrate holding surface 2a and the mold holding surface 42a are illustrated to have a configuration including the same regions, but the present disclosure is not limited thereto, and the numbers of regions or the region shapes in the substrate holding surface 2a and the mold holding surface 42a may be different.

FIG. 3B is a diagram illustrating the course of the mold releasing process. Specifically, FIG. 3B illustrates some of the processes illustrated in FIGS. 2E to 2F. At the time point at which the mold releasing process is started as illustrated in FIG. 2E, the controller 35 controls the suction forces of the substrate chuck 2 and the holding member 42 such that the suction force is the largest in the outer peripheral region of each of the substrate holding surface 2a and the mold holding surface 42a. In other words, the controller 35 controls the suction forces of the substrate chuck 2 and the holding member 42 such that the suction force of the outer peripheral region 52 is larger than the suction forces in the central region 50 and the intermediate region 51 at the time point at which the mold releasing process is started. Specifically, for example, the suction force in the outer peripheral region 52 is set to -100 kPa, the suction force in the intermediate region 51 is set to -30 kPa, and the suction force in the central region 50 is set to 0 kPa (no suction). When the holding member 42 is raised by the head 40 in this state, the separation between the super straight 11 and the cured composition 5 on the substrate is performed first from the outer peripheral part of the super straight 11. That is, while the holding member 42 is being raised, the outer peripheral part of the super straight 11 is separated (released) from the composition 5, and the central part of the super straight 11 is still in contact with the composition 5.

Thereafter, the controller 35 performs control such that the suction forces in the intermediate region 51 and the central region 50 are gradually close to the suction force in the outer peripheral region 52 in parallel with raising of the holding member 42. In this way, in the mold releasing process of separating the super straight 11 from the cured composition 5 on the substrate 1, the separation starts from the outer peripheral part and the central part is separated finally, whereby releasing from the composition 5 is completed. With this mold releasing process, it is possible to reduce (distribute) a bonding force between the super straight and the composition which is applied at the time of release and to prevent departure of the substrate or the super straight from the holding member (dechuck) during the mold releasing process.

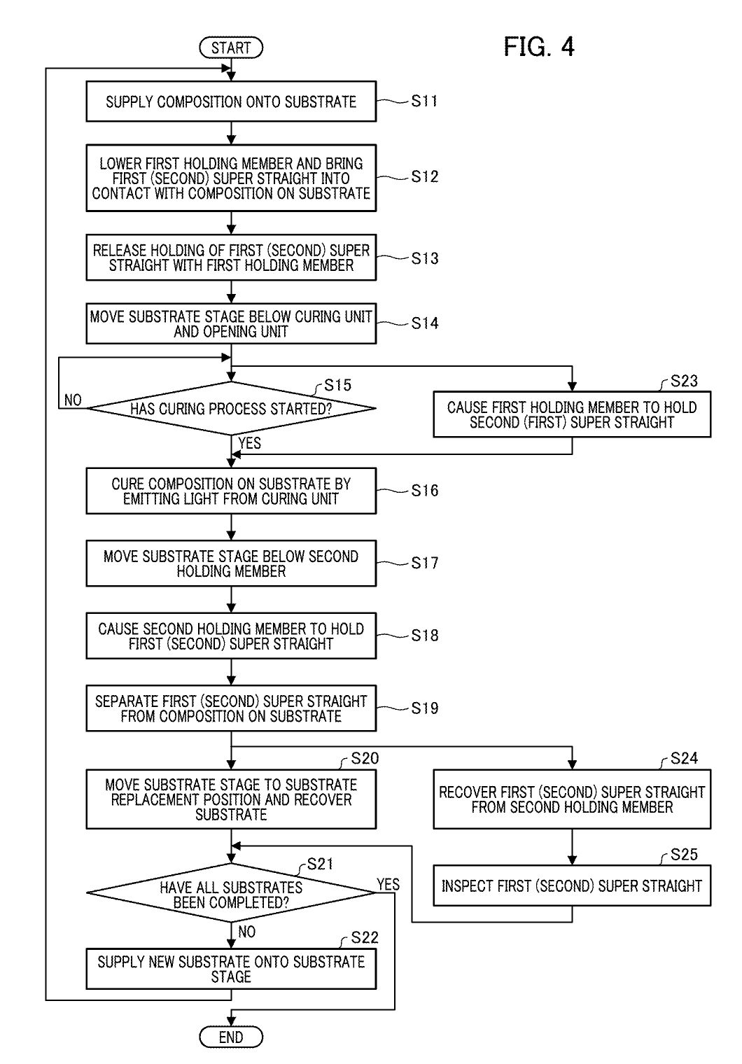

FIG. 4 is a flowchart illustrating the flattening process using the flattening apparatus 100 according to the first embodiment. Here, the flattening process is performed on a plurality of substrates using the flattening apparatus 100. The flowchart illustrated in FIG. 4 can be performed under the control of the controller 35. A super straight used in description of the flowchart includes two super straights of the super straight 11 and the super straight 41.

In Step S11, the controller 35 supplies a composition 5 as a plurality of droplets onto a substrate 1 using the supply unit 20. For example, the controller 35 can supply the composition 5 as a plurality of droplets onto the substrate 1 by causing the supply unit 20 to eject the composition 5 as a plurality of droplets while moving the substrate 1 below the supply unit 20.

In Step S12, the controller 35 brings the super straight 11 into contact with the composition 5 on the substrate 1 by lowering the holding member 12 holding the super straight 11 using the head 13. Step S12 is the same as described above with reference to FIGS. 2A and 2B, and thus detailed description thereof will be omitted.

In Step S13, the controller 35 releases holding of the super straight 11 with the holding member 12. Step S13 is the same as described above with reference to FIG. 2C, and thus detailed description thereof will be omitted. Here, the controller 35 raises the holding member 12 using the head 13 such that the holding member 12 and the super straight 11 are separated after the holding of the super straight 11 with the holding member 12 has been released.

In Step S14, the controller 35 moves the substrate stage 3 below the opening unit 28. In Step S15, the controller 35 determines whether a curing process is to be started. For example, the controller 35 can determine a start timing of the curing process on the basis of image information acquired from the spread camera 26. As described above with reference to FIG. 2B, contact between the super straight 11 and the composition 5 on the substrate 1 is started from the central part of the super straight 11. Then, the composition 5 supplied (disposed) as a plurality of droplets on the substrate 1 are coupled with the composition 5 of neighboring other droplets, spreads to the outside of the substrate 1 between the super straight 11 and the substrate 1, and changes to a liquid film. Accordingly, when the curing process is started immediately after the substrate stage 3 has been moved below the opening unit 28, the composition 5 on the outer peripheral part of the substrate 1 is cured in a state in which the composition is droplets, and thus the liquid film of the composition 5 between the super straight 11 and the substrate 1 may be discontinuous. Accordingly, the controller 35 determines that the curing process is to be started after the composition 5 has spread over the whole area of the substrate 1 on the basis of image information acquired from the spread camera 26.

When it is determined in Step S15 that the curing process is to be started (YES), the process flow proceeds to Step S16. At the time point at which the substrate stage has been moved below the opening unit 28 in Step S14, the composition 5 may have spread already over the whole area of the substrate 1. In this case, Step S15 may be skipped, and the curing process may be started immediately after the substrate stage 3 has been moved below the opening unit 28.

In Step S23, the controller 35 causes the holding member 12 to hold the super straight 41 using a mold carrying unit (not illustrated). Here, for example, Step S23 is performed after Step S14 has been completed and is performed in parallel with Step S15. When the substrate stage 3 located below the holding member 12 is moved below the opening unit 28 in Step S14, a space for allowing a hand of the mold carrying unit carrying the super straight 41 to enter below the holding member 12 is secured. Accordingly, it is preferable that Step S23 be performed after the substrate stage 3 located below the holding member 12 has been moved below the opening unit 28 in Step S14 to secure a space for allowing the hand of the mold carrying unit to enter below the holding member 12. When the substrate stage 3 is located below the holding member 12 but the space for allowing the hand of the mold carrying unit to enter below the holding member 12 can be secured in the apparatus, Step S23 may be performed before Step S14 as long as the holding of the super straight 11 with the holding member 12 has been released in Step S13.

Holding of the super straight 41 with the holding member 12 and retracting of the hand of the mold carrying unit from below the holding member 12 have only to be completed until the substrate stage 3 returns to below the holding member 12 again. That is, Step S23 has only to be completed before Step S12 for a next substrate. It is preferable that Step S23 be performed in a state in which the substrate stage 3 stops. In the state in which the substrate stage 3 is driven, particles are likely to be generated in the apparatus. Accordingly, by performing Step S23 in the state in which the substrate stage 3 stops, it is possible to curb attachment of particles to the super straight 41. The super straight 41 is supplied to the holding member 12 in a state in which XYθ positions have been corrected via a pre-alignment unit which is not illustrated before the super straight 41 is held by the holding member 12.

In Step S16, the controller 35 irradiates the composition 5 between the super straight 11 and the substrate 1 with light 30 to cure the composition 5 by causing the curing unit 24 to emit the light 30. Step S16 is the same as described above with reference to FIG. 2D, and thus detailed description thereof will be omitted.

In Step S17, the controller 35 moves the substrate stage 3 to below the holding member 42. Thereafter, the process of releasing the super straight 11 using the holding member 42 is started by the controller 35.

In Step S18, the controller 35 brings the holding member 42 into contact with the super straight 11 by lowering the holding member 42 using the head 40 and causes the holding member 42 to hold the super straight 11.

In Step S19, the controller 35 separates the super straight 11 from the cured composition 5 on the substrate 1 by raising the holding member 42 holding the super straight 11 using the head 40. Accordingly, a flattened film formed of the cured composition 5 can be formed on the substrate 1. Steps S18 and S19 are the same as described above with reference to FIGS. 2E and 2F, and thus detailed description thereof will be omitted.

In Step S20, the controller 35 moves the substrate stage 3 to a substrate replacement position in order to recover the substrate 1 on which the flattened film has been formed. When the substrate replacement position is divided into a substrate supply position and a substrate recovery position, the substrate stage 3 is moved to the substrate recovery position. Then, the substrate 1 on the substrate chuck 2 is recovered by a substrate carrying unit (not illustrated).

In Step S21, the controller 35 determines whether the flattening process on all substrates has ended. When the flattening process on all substrates has not ended (NO), that is, when an unprocessed substrate remains, the process flow proceeds to Step S22. In Step S22, the controller 35 supplies a new substrate (a second substrate) to which the composition 5 has not been supplied to the substrate chuck 2. When the substrate replacement position is divided into a substrate supply position and a substrate recovery position, a new substrate is supplied onto the substrate chuck 2 by the substrate carrying unit (not illustrated) after the substrate stage 3 has been moved to the substrate supply position.

On the other hand, when the flattening process on all substrates has ended (YES in Step S21), that is, when no unprocessed substrate remains, the process flow ends.

In Step S24, the controller 35 recovers the super straight 11 from the holding member 42 using the mold carrying unit (not illustrated). Here, Step S24 is performed, for example, in parallel with Step S20. When the super straight 11 is recovered by the mold carrying unit, a space for allowing the hand of the mold carrying unit to enter below the holding member 42 is necessary. Accordingly, after the substrate stage 3 has been moved to the substrate replacement position in Step S20 and after the space for allowing the hand of the mold carrying unit to enter below the holding member 42 has been secured, it is preferable that recovery of the super straight 11 using the mold carrying unit be started. When the substrate stage 3 is located below the holding member 42 but the space for allowing the hand of the mold carrying unit to enter below the holding member 42 can be secured in the apparatus, Step S24 may not be performed in parallel with Step S20 as long as the super straight 11 has been separated from the cured composition 5 on the substrate 1, that is, as long as the mold releasing process has been completed in Step S19. It is preferable that recovery of the super straight 11 be performed immediately when the super straight 11 can be recovered by the mold carrying unit, that is, immediately after the mold releasing process has been completed.

In Step S25, the controller 35 causes the inspection unit 32 to inspect the super straight 11 recovered from the holding member 42. In this inspection, inspection of flatness of the flat surface 11a of the super straight 11, inspection of whether there are particles (particulates) or scratches (stains) on the flat surface 11a and the rear surface 11b, inspection of attachment of foreign matter, and the like are performed. Particularly, in an outer peripheral part of a super straight, the composition 5 protruding from an outer peripheral edge of the substrate 1 may be broken at the time of release, and the mold releasing process may be completed in a state in which a part of the composition 5 is attached as foreign matter to the super straight. In the inspection, such foreign matter can be detected. It is preferable that the inspection include measurement in a noncontact manner using a laser measuring device or an optical profiler. When it is determined in the inspection that the super straight 11 is not reusable, the super straight 11 is returned to rework and is replaced with a new super straight. This inspection is preferably performed whenever the super straight has been recovered from the holding member 42, but the present disclosure is not limited thereto. Step S25 may be skipped, and the inspection may be performed whenever the flattening process on a plurality of substrates has been performed.

Referring back to Step S22, after Step S22 has ended, the flattening process is performed on a second substrate 1 supplied to the substrate stage 3 by the super straight 41 held by the holding member 12. That is, the processes of Steps S11 to S25 on the second substrate 1 are performed while a first super straight is replaced with a second super straight and the second super straight is replaced with the first super straight. Specifically, the super straight 11 is held by the holding member 42, and the super straight 11 is released from the cured composition 5 on the substrate 1. Thereafter, the super straight 11 is recovered from the holding member 42, the super straight 41 held by the holding member 12 is released from the holding member 12, and then the super straight 11 is held by the holding member 12 again. In this way, a series of processes of the flattening process using the super straight 11 and the super straight 41 are repeated until the flattening process on all substrates has ended in Step S21.

Before the super straight is held by the holding member 12, the super straight is supplied to the holding member 12 in a state in which the XYθ position has been corrected via the pre-alignment unit which is not illustrated.

In this way, in the present embodiment, by alternately using the super straight 11 and the super straight 41, it is possible to continuously perform the flattening process on a plurality of substrates without delaying the flattening process. Specifically, the wait time of the substrate stage required for replacement of the super straight can be reduced to almost 0. With the method of releasing the super straight from the cured composition 5 using the holding member 12, since the holding member 12 cannot used for the flattening process when the super straight is replaced with a new super straight, the substrate stage needs to wait. On the other hand, in the present embodiment, since a new super straight can be held by the holding member 12 while the super straight is released using the holding member 42, the substrate stage does not need to wait.

In the present embodiment, an example in which the head 13 supporting the holding member 12, the opening unit 28 emitting light from the curing unit 24, and the head 40 supporting the holding member 42 are disposed at different positions, that is, at non-overlap positions, in the XY plane direction has been described. However, the head 13 supporting the holding member 12 and the opening unit 28 emitting light from the curing unit 24 may be disposed at an overlap position in the XY plane direction. That is, light from the curing unit 24 may be applied to the composition 5 on the substrate 1 via the plate optical device 15 of the head 13. In this case, it is possible to skip Step S14 of the flowchart illustrated in FIG. 4 and to decrease the size of the apparatus as a whole. With this configuration, it is preferable that Step S22 be performed after the substrate stage 3 located below the holding member 12 has been moved to below the holding member 42 and the space for allowing the hand of the mold carrying unit to enter below the holding member 12 has been secured in Step S17.

In the present embodiment, an example in which the flattening apparatus is used as the film formation apparatus has been described. However, the present embodiment can also be applied to an imprint apparatus that transfers a pattern of a mold to an imprint material by bringing the mold having an unevenness pattern into contact with the imprint material which is a composition of a substrate.

### Embodiment of article manufacturing method

An article manufacturing method according to an embodiment of the present disclosure is suitable for manufacturing a micro device such as a semiconductor device or an article such as a device having a microstructure. The article manufacturing method according to the present embodiment includes a step of forming a layer of a composition on a substrate using the film formation apparatus and a step of processing the substrate on which the layer has been formed. This manufacturing method includes other known steps (oxidation, film formation, vapor deposition, doping, flattening, etching, resist removal, dicing, bonding, packaging, and the like). The article manufacturing method according to the present embodiment is more advantageous in at least one of performance, quality, productivity, and production cost of an article in comparison with a method according to the related art.

The pattern of a cured composition formed by the imprint apparatus is used permanently as at least a part of various articles or temporarily at the time of manufacturing various articles. An article is an electrical circuit device, an optical device, an MEMS, a recording device, a sensor, or a mold. Examples of the electrical circuit device include volatile or nonvolatile semiconductor memories such as a DRAM, an SRAM, a flash memory, and an MRAM and semiconductor devices such as an LSI, a CCD, an image sensor, and an FPGA. Examples of the mold include a mold for imprinting.

The pattern of a cured composition is used as a constituent member of at least a part of the article without any change or is temporarily used as a resist mask. After etching, ion implantation, or the like has been performed in the substrate processing step, the resist mask is removed.

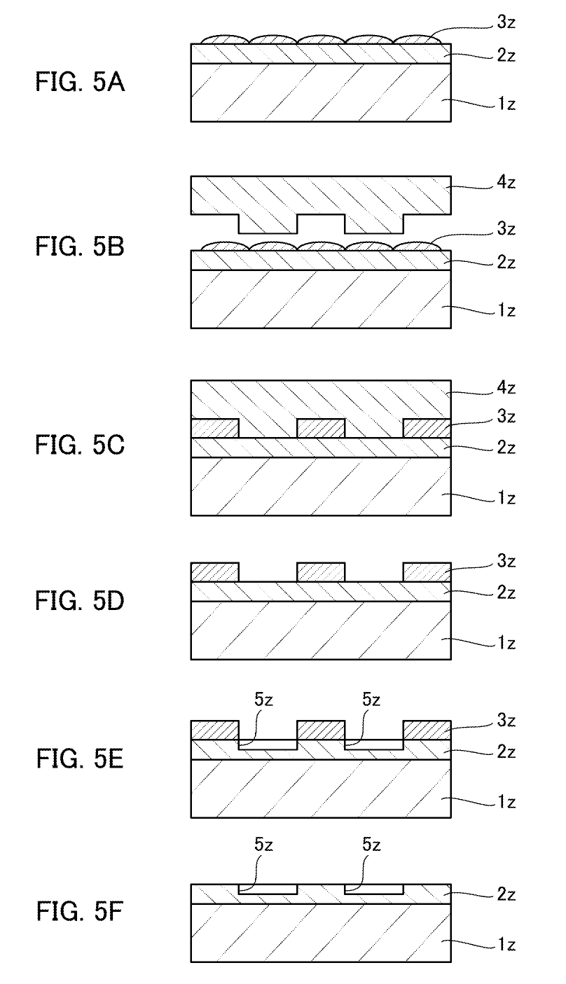

A specific article manufacturing method will be described below. FIGS. 5A to 5F are diagrams illustrating an article manufacturing method. As illustrated in FIG. 5A, a substrate 1z such as a silicon wafer in which a processing material 2z such as an insulator has been formed on the surface is prepared, and an imprint material 3z is applied to the surface of the processing material 2z using an ink jet method or the like. Here, a state in which the imprint material 3z with a shape of a plurality of droplets is applied to the substrate is illustrated.

As illustrated in FIG. 5B, a mold 4z for imprinting is disposed such that a surface on which an uneven pattern is formed faces the imprint material 3z on the substrate. As illustrated in FIG. 5C, the substrate 1z to which the imprint material 3z is applied is brought into contact with the mold 4z, and a pressure is applied thereto. A gap between the mold 4z and the processing material 2z is filled with the imprint material 3z. When light which is curing energy is applied via the mold 4z in this state, the imprint material 3z is cured.

As illustrated in FIG. 5D, when the mold 4z and the substrate 1z are separated after the imprint material 3z has been cured, a pattern of a cured structure of the imprint material 3z is formed on the substrate 1z. This pattern of a cured structure has a shape in which a recessed part of the mold corresponds to a protruding part of the cured structure and a protruding part of the mold corresponds to a recessed part of the cured structure, that is, an unevenness pattern of the mold 4z is transferred to the imprint material 3z.

As illustrated in FIG. 5E, when etching is performed using the pattern of the cured structure as an etching-resistant mask, a part having no cured structure or having a cured structure remaining thin on the surface of the processing material 2z is removed to be a groove 5z. As illustrated in FIG. 5F, when the pattern of the cured structure is removed, an article in which the groove 5z is formed on the surface of the processing material 2z can be obtained. The pattern of the cured structure is removed herein, but the pattern of the cured structure may not be removed after the processing and may be used as, for example, an interlayer insulating film included in a semiconductor device, that is, a constituent member of an article.

In the example, a mold for transferring a circuit pattern provided with an unevenness pattern is used as the mold 4z, but a member (a plane template) having a flat surface without an unevenness pattern may be used.

### Other embodiments

While exemplary embodiments of the present disclosure have been described above, the present disclosure is not limited to the embodiments and can be modified or altered in various forms within the scope of the gist thereof.

The present disclosure can also be realized by transmitting a program for realizing some or all of one or more functions in the aforementioned embodiments to a system or an apparatus via a network or a storage medium and causing one or more processors in a computer of the system or the apparatus to read and execute the program. The present disclosure can also be realized by a circuit (for example, an ASIC) for realizing one or more functions.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-065153, filed April 10, 2025, which is herein in its entirety.

What is claimed is:

1. A film formation apparatus that performs a film forming process of forming a film of a curable composition on a substrate using a shaping member, the film formation apparatus comprising:
a substrate holding member that holds the substrate;
a first holding member that holds the shaping member, brings the shaping member into contact with the curable composition on the substrate, and releases holding of the shaping member; and
a second holding member that holds the shaping member to perform a mold releasing process of separating the shaping member from the cured curable composition after the curable composition has been cured.

2. The film formation apparatus according to claim 1, wherein the second holding member holds the shaping member with an area larger than that of the first holding member.

3. The film formation apparatus according to claim 1, wherein the first holding member holds an outer peripheral part of the shaping member, and
wherein the second holding member holds the outer peripheral part of the shaping member and at least a part inside the outer peripheral part.

4. The film formation apparatus according to claim 3, further comprising a controller configured to control the second holding member,
wherein the second holding member is able to hold the shaping member with different holding forces in the outer peripheral part and the inner part thereof, and
wherein the controller controls the second holding member such that the inner part is held with a smaller holding force than that of the outer peripheral part at a time point at which the mold releasing process starts and the holding force of the inner part increases with the process of the mold releasing process.

5. The film formation apparatus according to claim 1, further comprising a controller configured to control the first holding member and the second holding member,
wherein the film forming process is performed using a first shaping member and a second shaping member different from the first shaping member, and
wherein the controller causes the first holding member to hold the second shaping member after holding of the first shaping member with the first holding member has been released in the film forming process using the first shaping member and until the mold releasing process on the first shaping member with the second holding member ends.

6. The film formation apparatus according to claim 5, wherein the controller causes the first holding member to hold the second shaping member from a process of curing the curable composition to end of the mold releasing process on the first shaping member with the second holding member in the film forming process using the first shaping member.

7. The film formation apparatus according to claim 6, wherein the controller causes the first holding member to hold the second shaping member when the substrate holding member stops.

8. The film formation apparatus according to claim 5, wherein the controller causes the second holding member to hold the first shaping member, recovers the first shaping member from the second holding member after the first shaping member has been released from the film on the substrate, and causes the first holding member to hold the first shaping member after the second shaping member held by the first holding member has been separated from the first holding member.

9. The film formation apparatus according to claim 1, further comprising an inspection unit configured to inspect the shaping member released from the film on the substrate by the second holding member and recovered from the second holding member before the shaping member is held by the first holding member.

10. The film formation apparatus according to claim 1, further comprising a light transmitting member for making a space above the shaping member surrounded by the first holding member and the shaping member held by the first holding member a closed space.

11. The film formation apparatus according to claim 1, further comprising an emission unit configured to emit energy for curing the curable composition on the substrate,
wherein the emission unit and the second holding member are disposed at positions not overlapping in a planar direction.

12. The film formation apparatus according to claim 10, further comprising an emission unit configured to emit energy for curing the curable composition on the substrate,
wherein the emission unit and the first holding member are disposed at a position overlapping in a planar direction.

13. The film formation apparatus according to claim 1, wherein the film formation apparatus is a flattening apparatus that forms a flat film of the curable composition on the substrate by bringing a flat part of the shaping member into contact with the curable composition.

14. A film formation method of performing a film forming process of forming a film of a curable composition on a substrate using a shaping member, the film formation method comprising:
holding the shaping member using a first holding member;
bringing the shaping member into contact with the curable composition on the substrate held by a substrate holding member;
releasing holding of the shaping member with the first holding member; and
holding the shaping member using a second holding member to perform a mold releasing process of separating the shaping member from the cured curable composition after the curable composition has been cured.

15. An article manufacturing method using a film formation apparatus that performs a film forming process of forming a film of a curable composition on a substrate using a shaping member and includes a substrate holding member that holds the substrate, a first holding member that holds the shaping member, brings the shaping member into contact with the curable composition on the substrate, and releases holding of the shaping member, and a second holding member that holds the shaping member to perform a mold releasing process of separating the shaping member from the cured curable composition after the curable composition has been cured, the article manufacturing method comprising:
a flattening process of flattening a composition of a substrate using the film formation apparatus;
a processing process of processing the substrate including the composition formed in the flattening process; and
a manufacturing process of manufacturing an article from the substrate processed in the processing process.
